(19) United States
(12) Patent Application Publication
(10) Pub. No.: US 2026/0095019 A1
(43) Pub. Date: Apr. 2, 2026

(54) LIGHT-EMITTING MODULE

(71) Applicant: NICHIA CORPORATION, Anan-shi (JP)

(72) Inventor: Kiyoshi ENOMOTO, Anan-shi (JP)

(21) Appl. No.: 19/346,274

(22) Filed: Sep. 30, 2025

(30) Foreign Application Priority Data
Oct. 2, 2024 (JP) 2024-173252

(51) Int. Cl. H01S 5/02315; H01S 5/068

(52) U.S. Cl. CPC H01S 5/02315; H01S 5/06804

(57) ABSTRACT

A light-emitting module includes a light-emitting device and a wiring board. The light-emitting device includes a substrate on which semiconductor laser elements are arranged along a longitudinal direction. The wiring board has a mounting surface including a first area on which the light-emitting device is mounted. The wiring board has a longitudinal direction extending in a first direction. The wiring board includes first and second fixing portions, a first electrode portion to which the substrate is joined, and a second electrode portion. The second electrode portion is configured to be connected to a connecting member for electrical connection to an external device. In the top view, the first area is located between the first and second fixing portions. The second fixing portion is disposed between the first and second electrode portions. The substrate has the longitudinal direction extending in the first direction.

### CROSS-REFERENCE TO RELATED APPLICATION

This application claims priority to Japanese Patent Application No. 2024-173252, filed on October 2, 2024, the disclosure of which is hereby incorporated by reference in its entirety.

### TECHNICAL FIELD

The present disclosure relates to a light-emitting module.

### BACKGROUND

Japanese Patent Publication No. 2024-42909 discloses a light-emitting module in which a light-emitting element is mounted on a wiring board. This light-emitting module is configured such that a through-hole provided in the wiring board can be used as a screw hole and fixed to other member.

### SUMMARY

An object of the disclosure is to provide a compact light-emitting module taking mounting capability into consideration.

As disclosed in several embodiments of the invention, a light-emitting module includes a light-emitting device and a wiring board. The light-emitting device includes a plurality of semiconductor laser elements and a substrate on which the plurality of semiconductor laser elements are arranged along a longitudinal direction of the substrate. The wiring board has a mounting surface including a first area on which the light-emitting device is mounted. The wiring board has a longitudinal direction extending in a first direction and a widthwise direction extending in a second direction perpendicular to the first direction in a top view that is viewed from a direction perpendicular to the mounting surface. The wiring board includes a first fixing portion and a second fixing portion at which the wiring board is configured to be fixed in place, a first electrode portion to which the substrate is joined for electrical connection to the plurality of semiconductor laser elements, and a second electrode portion electrically connected to the first electrode portion. The second electrode portion is configured to be connected to a connecting member for electrical connection of the light-emitting device to an external device. In the top view, the first area is located between the first fixing portion and the second fixing portion. The second fixing portion is disposed between the first electrode portion and the second electrode portion. The substrate has the longitudinal direction extending in the first direction and a widthwise direction extending in the second direction.

In at least one of the one or more embodiments of the invention disclosed herein, a compact light-emitting module taking mounting capability into consideration can be provided.

### BRIEF DESCRIPTION OF THE DRAWINGS

FIG. 1 is a perspective view of the light-emitting module according to one embodiment.

FIG. 2 is an upper view of the light-emitting module according to one embodiment.

FIG. 3 is a lateral side view of the light-emitting module according to one embodiment.

FIG. 4 is a perspective view of the light-emitting device according to one embodiment.

FIG. 5 is a lateral side view of the light-emitting device shown in FIG. 4.

FIG. 6A is an upper view of the light-emitting device according to one embodiment.

FIG. 6B is a sectional view of the light-emitting device as taken along line VIB-VIB in FIG. 6A.

FIG. 7 is a perspective view of the package according to one embodiment.

FIG. 8A is an upper view of the package according to one embodiment.

FIG. 8B is a sectional view of the package according to one embodiment as taken along line VIIIB-VIIIB in FIG. 8A.

FIG. 9 is an upper view of the substrate according to one embodiment.

FIG. 10 is a lower view of the substrate according to one embodiment.

FIG. 11 is a section view as taken along line XI-XI in FIG. 9.

FIG. 12 is an upper view for the explanation of the internal structure of the light-emitting device according to one embodiment.

FIG. 13A is a view in which a wiring pattern is overlapped on the upper view of the wiring board according to one embodiment.

FIG. 13B is an upper view of the wiring pattern on the wiring board according to one embodiment.

FIG. 13C is illustrative of the wiring pattern on the wiring board according to one embodiment.

FIG. 14 is a perspective view of the light-emitting module according to another embodiment.

FIG. 15A is a view in which a wiring pattern is overlapped on the upper view of the wiring board according to another embodiment.

FIG. 15B is an upper view of the wiring pattern on the wiring board according to another embodiment.

FIG. 15C is illustrative of the wiring pattern on the wiring board according to another embodiment.

### DETAILED DESCRIPTION

Concerning polygons such as triangles, and quadrangles referred to in the present description and claims, it is understood that the word “polygon” includes a polygon rounded, chamfered, round chamfered or otherwise configured at its corners. The word “polygon” also includes a polygon that is configured at an intermediate portion of any side in addition to the corner (end of each side). In short, a partially processed shape based on a polygon is also encompassed in the interpretation of the “polygon” described in the present description and claims.

Additionally, the same is also true of words or terms referring to a specific shape such as a trapezoid, a circle, or projections and depressions as well as each side forming that shape. In short, even when the corner or an intermediate portion of a certain side is processed, the processed portion is encompassed in the interpretation of the “side”. It is noted here that when the “polygon” or “side” not subjected to any processing is discriminated from the processed shape, the word “strict” is added thereto such as “strict quadrangle”.

It is understood that in the present description and claims, phrases such as “top/bottom (upward/downward)”, above/below”, “left/right”, “front/back”, “before/after (forward/rearward), and “frontward/backward” refer simply to relative positions, orientations, and directions; they does not need to coincide with relations in use.

In the drawings, directions such as X direction, Y direction, and Z direction are often indicated by arrows. The direction indicated by such an arrow is aligned among a plurality of drawings showing the same embodiment. Here, the direction of an arrow to which X, Y, and Z are added is a positive direction, and the opposite direction is a negative direction. For instance, X given at the tip of a certain arrow is indicative of an X direction, and a positive direction. It is noted here that the direction that is the X direction and positive direction is called the “X positive direction”, whereas the opposite direction is called the “X negative direction”. It is understood that when there is a reference to the “X direction”, it indicates both positive and negative directions. The same is also true of the Y direction, and the Z direction.

In the present description, it is understood that when the phrase “one or plural” is added to a certain subject for explanation thereof, configurations where there is one subject and there are plural subjects are collectively described. Accordingly, the explanation specified by the phrase “one or plural” is understood to support an embodiment including one or plural subjects, an embodiment including at least one subject, and an embodiment including a plurality of subjects.

In the description for “one or each” subject matter given herein, an explanation of one subject matter in an embodiment including one subject matter, an explanation of one subject matter in an embodiment including a plurality of subject matters, and an explanation of plural subject matters in an embodiment including a plurality of subject matters are collectively described. Accordingly, the description relating to the explanation of “one or each” subject matter provides full support for an explanation of one subject matter in an embodiment comprising one subject matter, an explanation of at least one subject matter in an embodiment comprising a plurality of subject matters, and an explanation of a plurality of subject matters in an embodiment comprising a plurality of subject matters.

When components are herein explained, “members”, and “portions” are often added thereto. The “member” is understood to refer to a single subject matter when physically viewed. The physically viewed single subject matter may be a subject matter viewed as one part in a manufacturing process. On the other hand, the “part” or “portion” is understood to refer to a subject matter that is not necessarily used as a physically viewed single matter. For instance, when a portion of one single member is partly viewed or a plurality of members are viewed as a single matter, the term “part” or “portion” is used.

Such distinguishing the “member” and the “part” or “portion” herein has no intent of consciously limiting the scope of rights in the interpretation of the doctrine of equivalents. In other words, even when there is a component called the “member” in the claims, Applicant does not necessarily recognize that viewing this component as a physical single matter is essential for the application of the present invention.

In the present description and the claims, when there is a plurality of certain components that are to be independently described, the “first” and “second” are often added to just before the components. There may be a case where the subject matters to be distinguished are different between the present description and the claims. Accordingly, even when the component having the same additional remark in the description is set forth in the claims, the subject matter specified by this component may possibly have no coincidence between the present description and the claims.

For instance, when there are components to be distinguished by additional remarks of the “first”, “second” and “third” in the present description and the components having additional remarks of the “first” and “third” are set forth in the claims, these components are distinguished by additional remarks of the “first” and “second” for the sake of visibility in the claims. In this case, it is understood that the components followed by the “first” and “second” refer to the components followed by the “first” and “third”. It is noted here that this rule may reasonably and flexibly be applied not only to components but also to other matters.

Some modes for carrying out the invention are now explained. With reference to the accompanying drawings, some specific modes for carrying out the invention; however, it is understood that the modes for carrying out the invention are not limited thereto. In other words, the embodiments set forth herein do not show only a mode of realizing the present invention. It is also understood that the size, position and so on of the member shown in each drawing are exaggerated for the sake of convenience of understanding.

### Embodiments

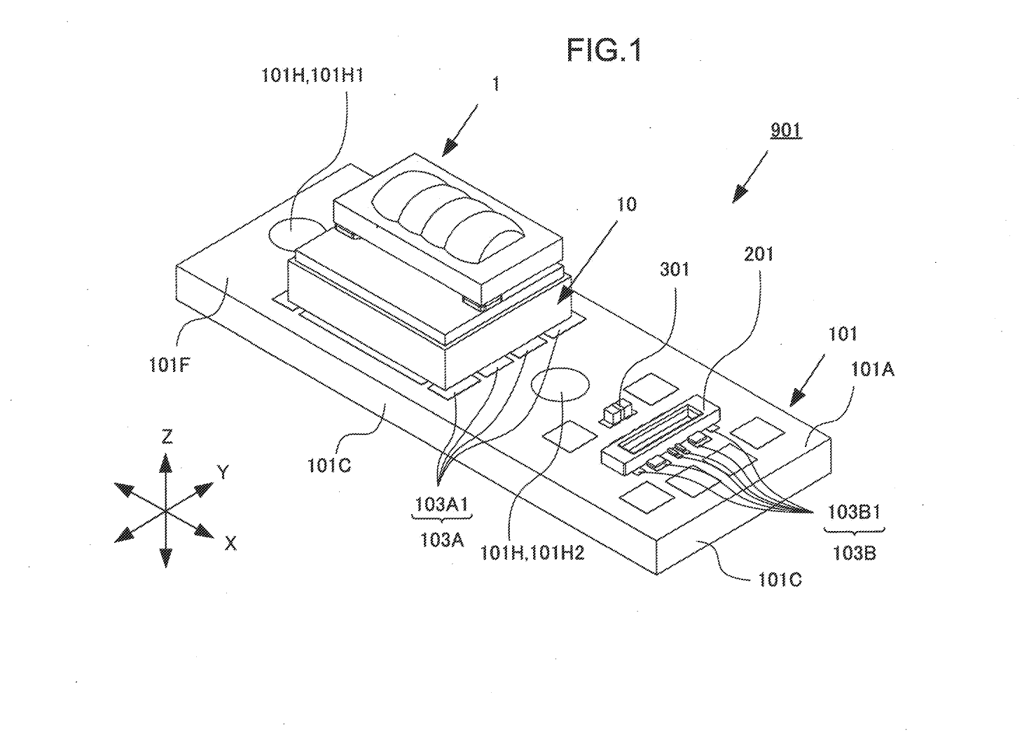

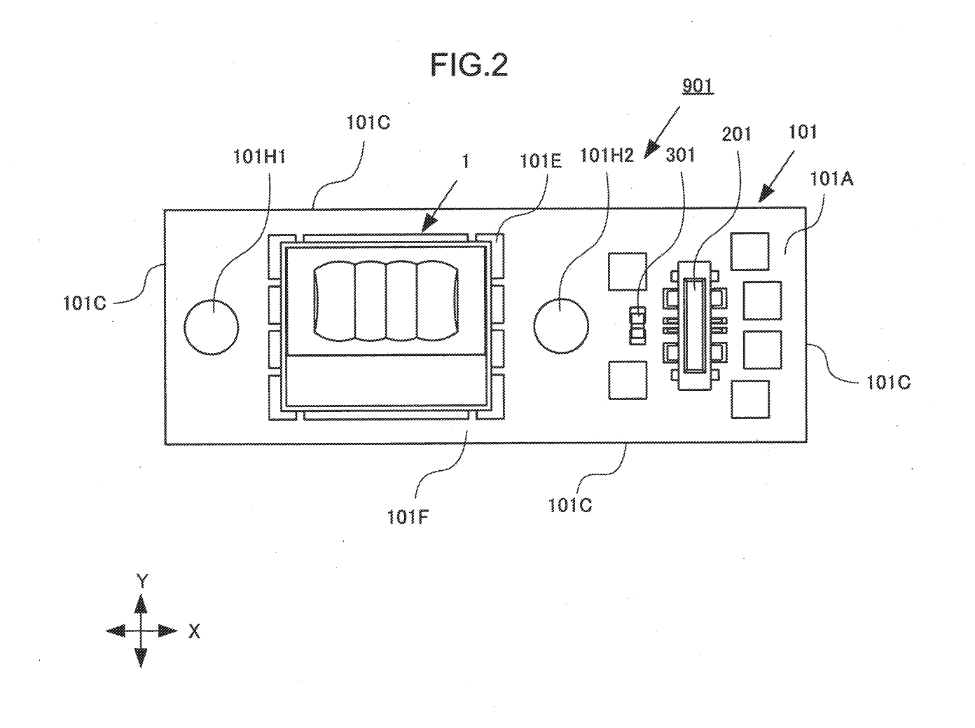

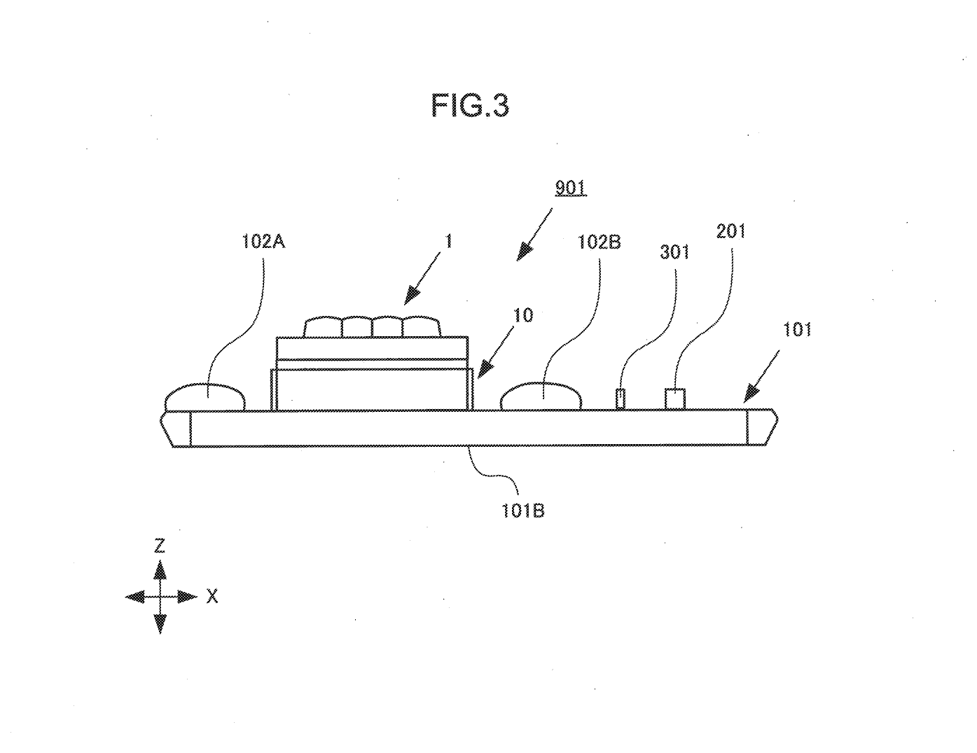

A light-emitting module 901 according to one embodiment of the invention is now explained. FIGS. 1, 2 and 3 are illustrative of one exemplary mode of the light-emitting module 901. FIG. 1 is a perspective view of the light-emitting module 901 according to one embodiment of the invention; FIG. 2 is an upper view of the light-emitting module 901; and FIG. 3 is a lateral side view of the light-emitting module 901.

The light-emitting module 901 comprises a plurality of components including a plurality of light-emitting devices 1, a wiring board 101, a connector 201, and a thermistor 301.

It is here understood that the light-emitting module 901 may also comprise other components. For instance, the light-emitting module 901 may comprise a light-emitting device different from the assemblies 1, and some of the plural components referred to herein may be omitted.

The light-emitting module 901 may comprise a light-emitting device 1 including one or more light-emitting elements 20 and a substrate 11 on which the one or more light-emitting elements 20 are mounted, and a wiring board 101 having a mounting surface including a first area 1A on which the light-emitting device 1 is mounted. A semiconductor laser element may be used for the light-emitting element 20. The wiring board 101 includes an electrode portion 101E for electrical connection of the light-emitting device 1 to the outside (e.g., an external device such as a power source). The electrode portion 101E is connected with a connecting member such as a connector 201 and a wire. The light-emitting module 901 may take a form including a connecting member such as a connector 201 or a wire. The light-emitting module 901 may further comprise a thermistor 301 operating as a temperature measuring element configured to measure temperatures.

Each component of the light-emitting module 901 is now explained.

### Light-Emitting Device 1

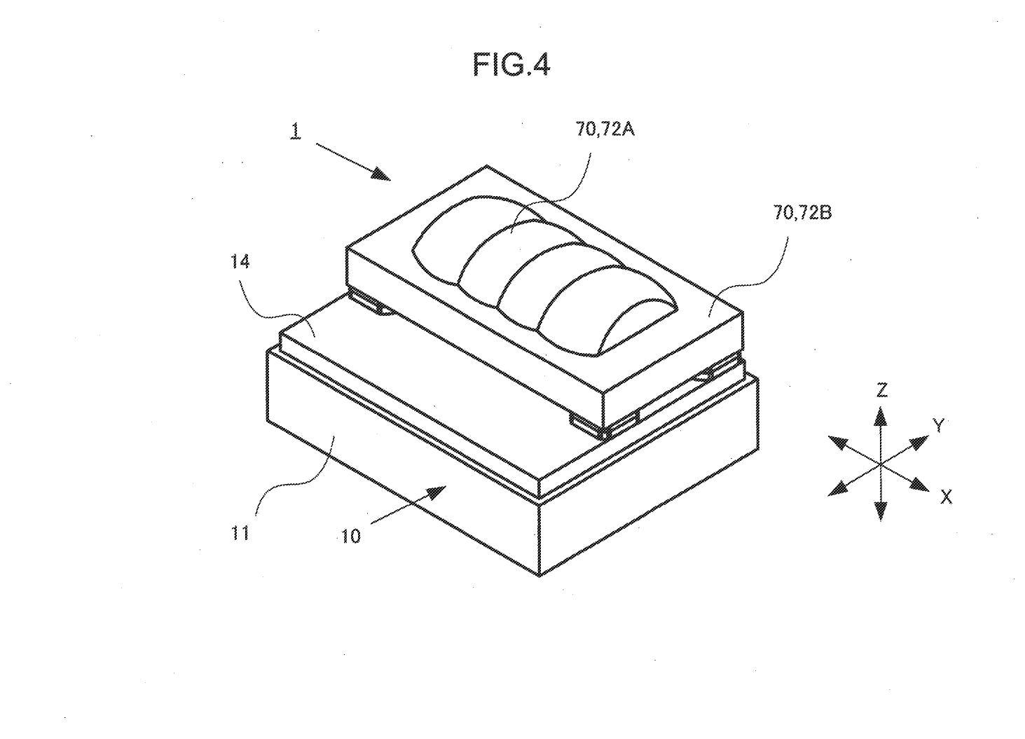

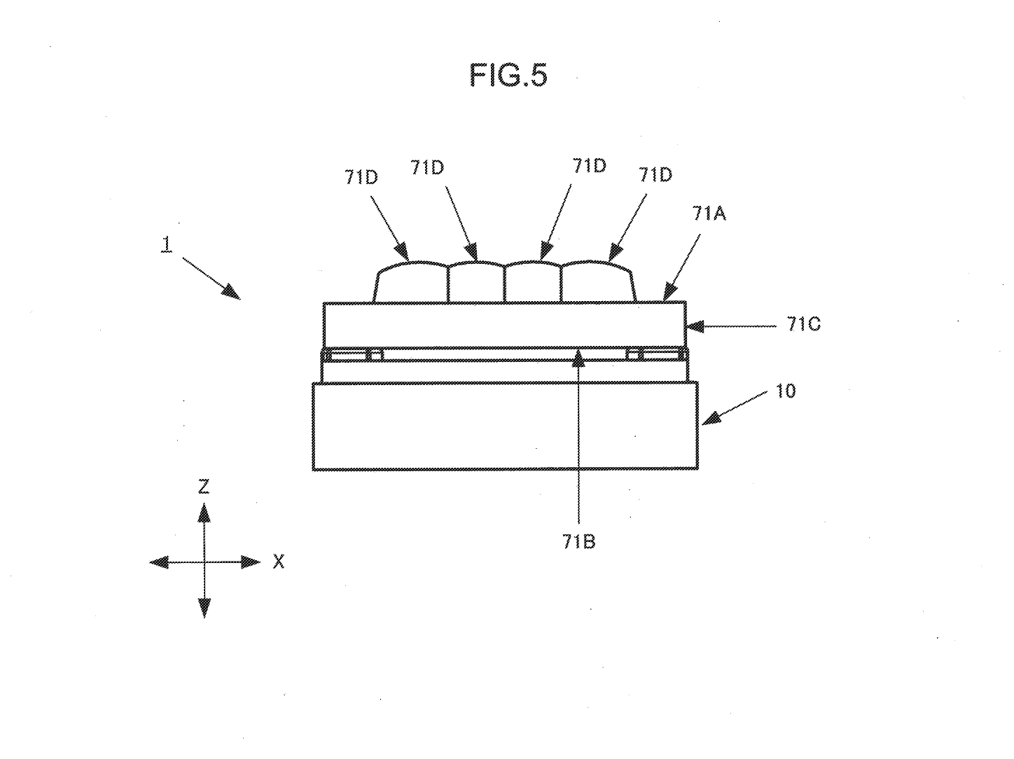

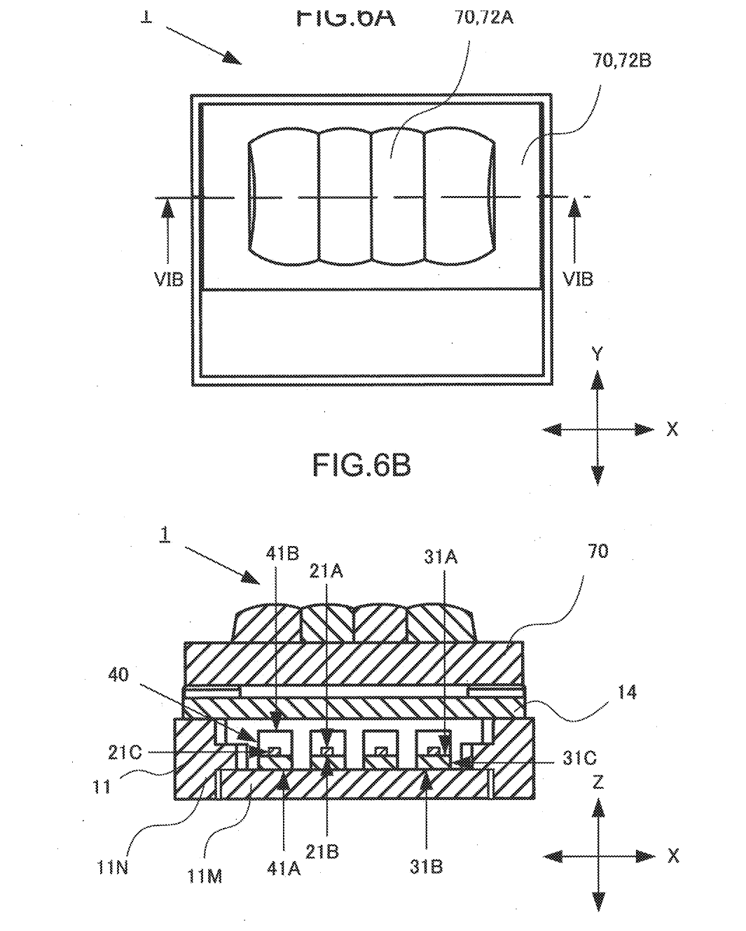

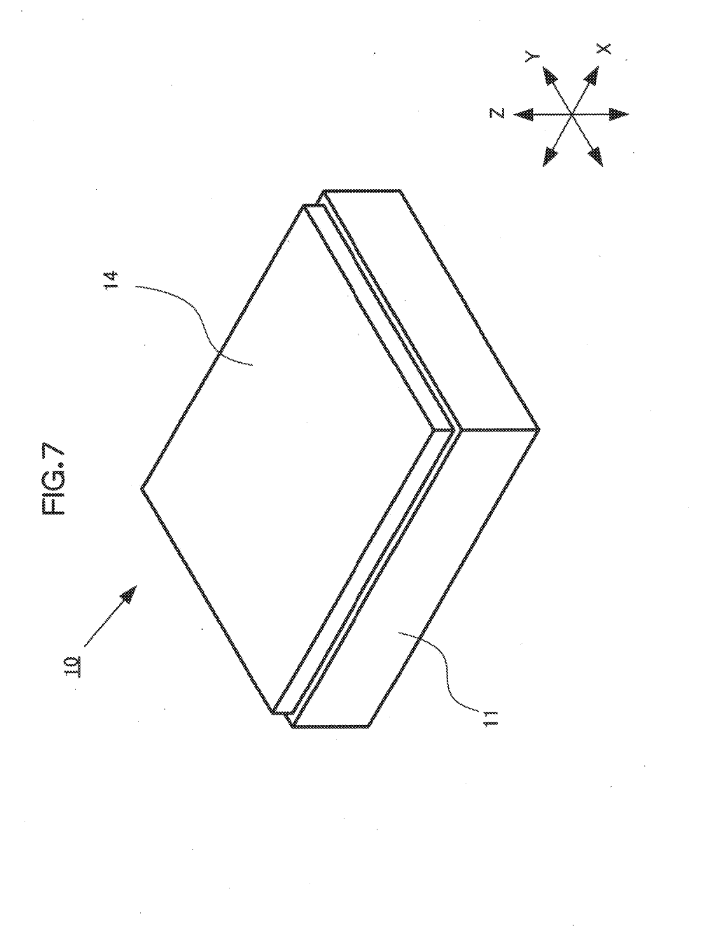

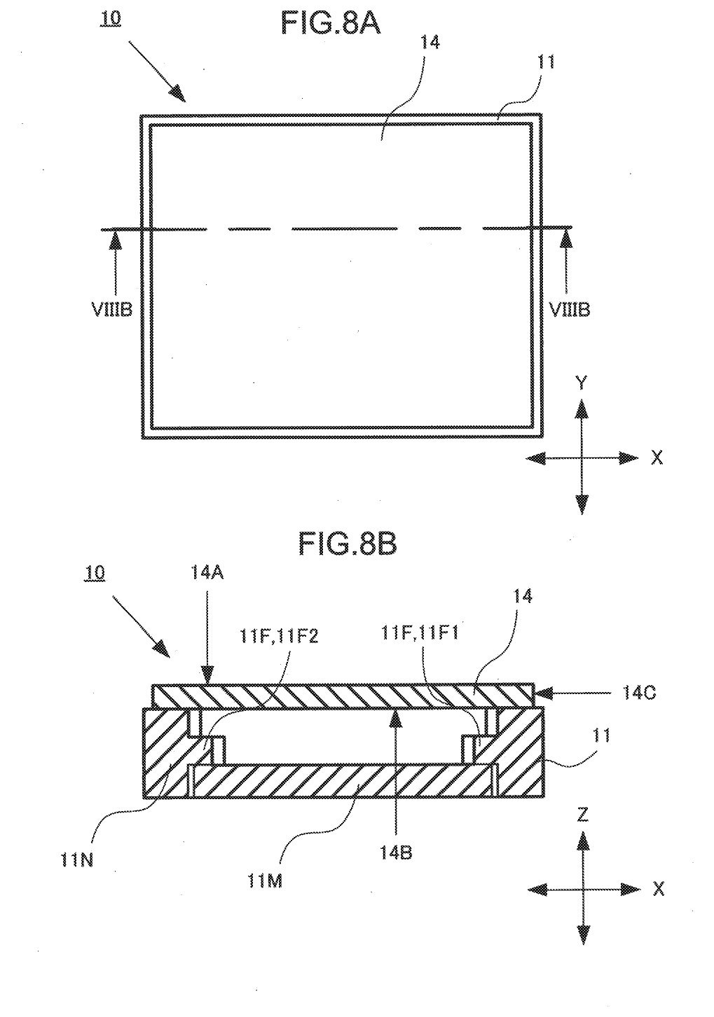

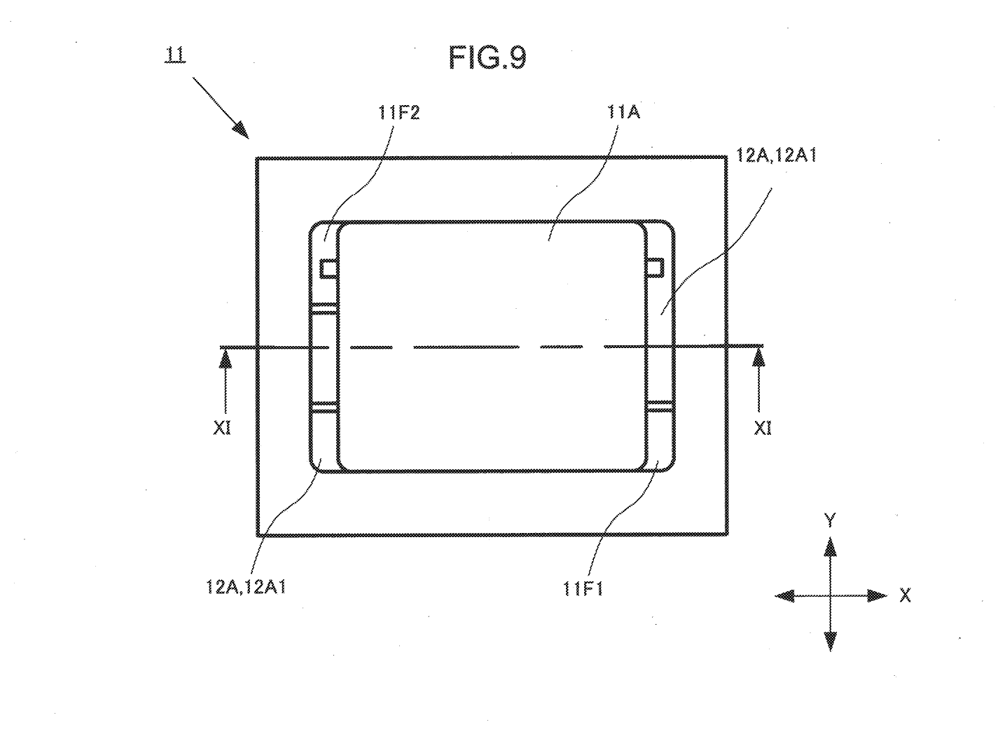

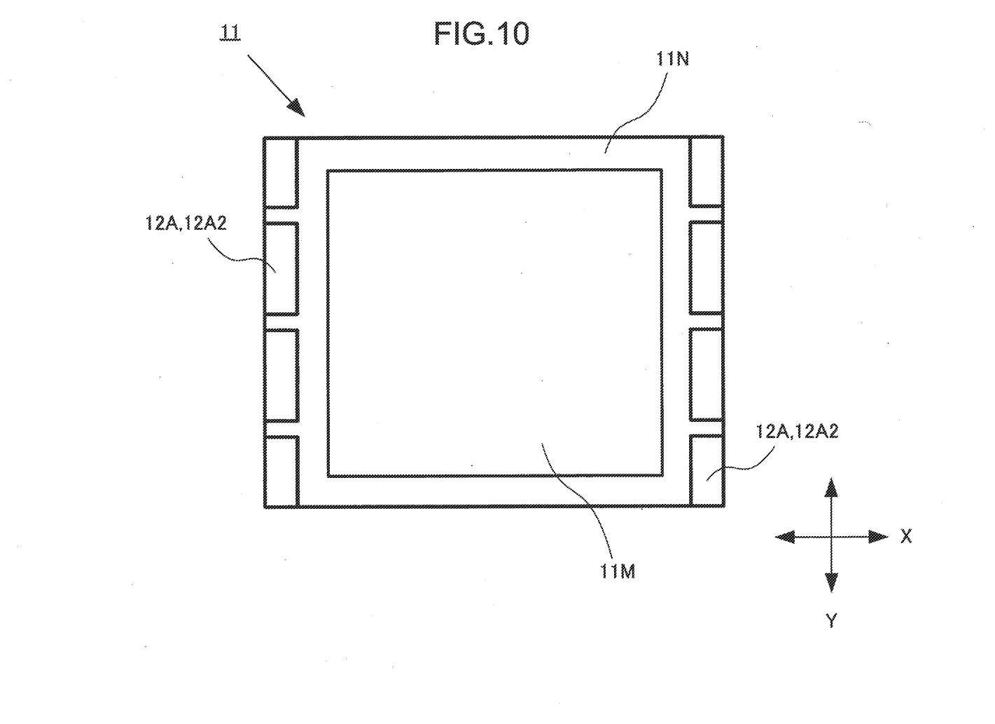

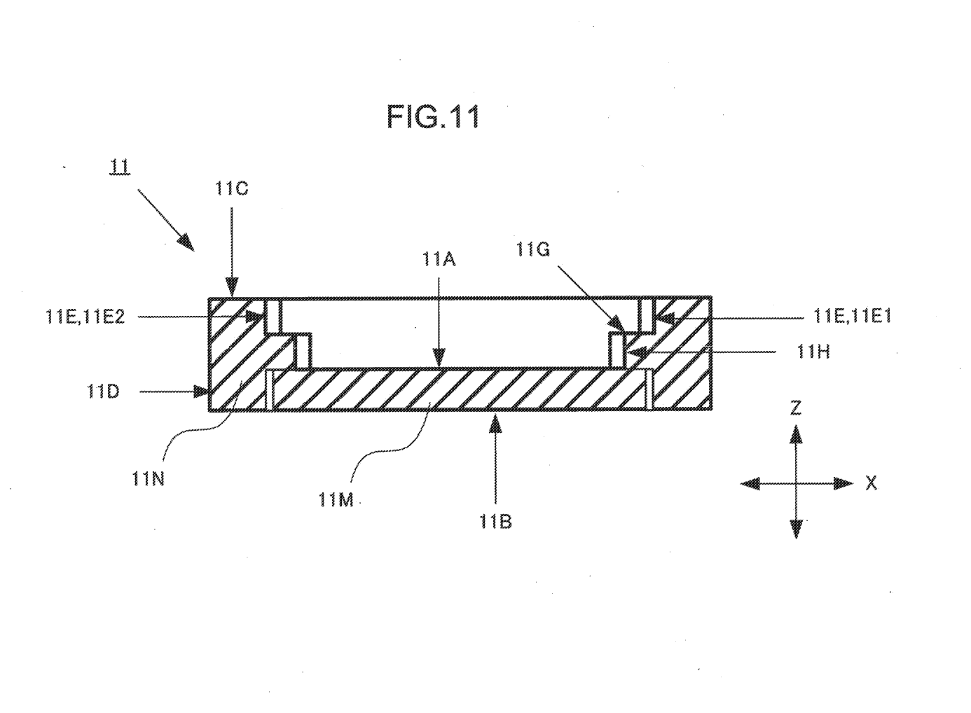

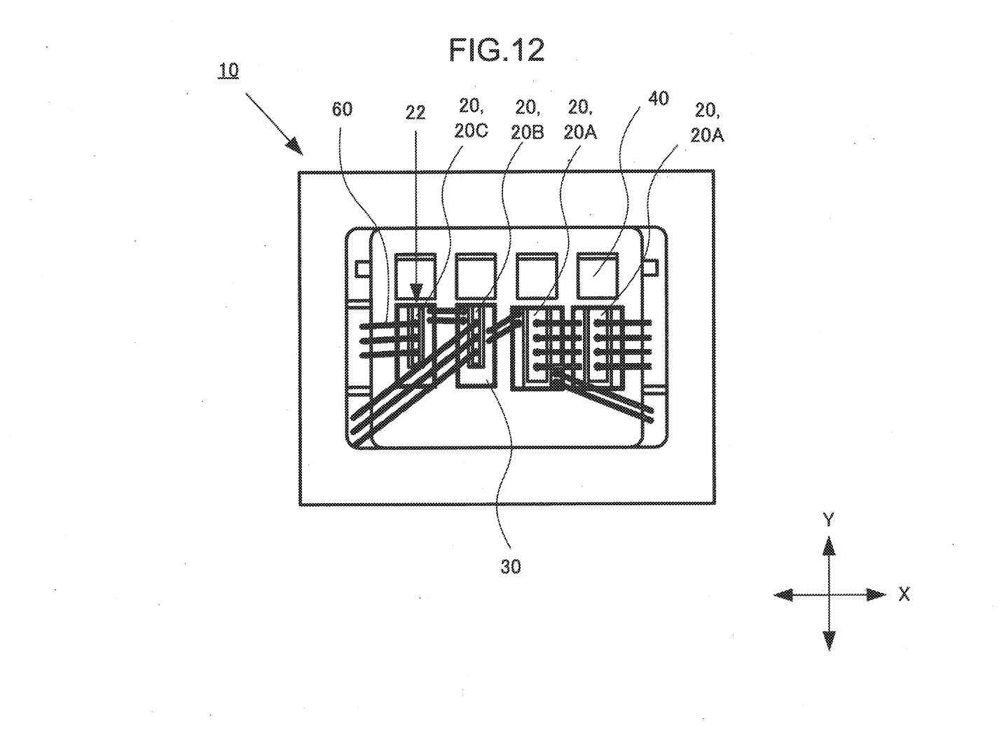

The light-emitting device 1 according to one embodiment is first explained. FIGS. 4 to 12 are illustrative of one exemplary form of the light-emitting device 1. FIG. 4 is a perspective view of the light-emitting device 1 according to one embodiment. FIG. 5 is a lateral side view corresponding to FIG. 4. FIG. 6A is an upper view of the light-emitting device according to one embodiment. FIG. 6B is a sectional view of the light-emitting device as taken along line VIB-VIB in FIG. 6A. FIG. 7 is a perspective view of the package according to one embodiment. FIG. 8A is an upper view of the package according to one embodiment. FIG. 8B is a sectional view of the package according to one embodiment as taken along line VIIIB-VIIIB in FIG. 8A. FIG. 9 is an upper view of the substrate according to one embodiment. FIG. 10 is a lower view of the substrate according to one embodiment. FIG. 11 is a sectional view as taken along line XI-XI in FIG. 9. FIG. 12 is an upper view for explanation of the internal structure of the light-emitting device according to one embodiment.

The light-emitting device 1 comprises a plurality of components. Plural such components include a package 10, one or more light-emitting elements 20, one or more sub-mounts 30, one or more reflecting members 40, a plurality of wires 60, and an optical member 70.

It is noted here that the light-emitting device 1 may further comprise other components. For instance, the light-emitting device 1 may include, apart from the one or more light devices 20, an additional light-emitting element or devices. It is also understood that some of the plural components referred herein do not need to be included in the light-emitting device 1.

Each of the components of the light-emitting device 1 is now explained.

### Package 10

The package 10 comprises a substrate 11 and a lid 14. The lid 14 is joined to the substrate 11, forming the package 10. In the package 10, an internal space is defined such that other components are located. This internal space is a closed space surrounded by the substrate 11 and lid 14. Such an internal space may be sealed up in a vacuum or airtight state.

In a top view, the package 10 has a rectangular outer edge form. This rectangular shape may include a long side and a short side. In the illustrated package 10, the long-side direction of this rectangular shape is the same as the X direction and the short-side direction is the same as the Y direction. In a top view, the outer edge shape of the package 10 is not necessarily rectangular.

Defined in the package 10 is an internal space in which other component(s) is located. A first upper surface 11A of the package 10 forms a part of an area that defines the internal space. Each inside surface 11E and a lower surface 14B of the package 10 form a part of an area that defines the internal space.

The substrate 11 has a first upper surface 11A and a lower surface 11B. The substrate 11 has a second upper surface 11C. The substrate 11 has one or plural outer surfaces 11D. The substrate 11 has one or plural inner surfaces 11E. The one or plural outer surfaces 11D intersect the second upper surface 11C. The one or plural outer surfaces 11D intersect the one or plural outer surfaces 11D intersect the lower surface 11B. The one or plural inner surfaces 11E intersect the second upper surface 11C.

In a top view, the outer edge shape of the substrate 11 is rectangular. In a top view, the outer edge shape of the substrate 11 is the same as the outer edge shape of the package 10. In a top view, the outer edge shape of the first upper surface 11A is rectangular. This rectangle may include a long side and a short side. The long-side direction of the first upper surface 11A is parallel with the long-side direction of the outer edge shape of the substrate 11. In a top view, the outer edge shape of the first upper surface 11A does not have to be rectangular.

In a top view, the first upper surface 11A is surrounded by the second upper surface 11C. The second upper surface 11C is an annular surface that surrounds the first upper surface 11A in a top view. The second upper surface 11C is an annular rectangular surface. A frame defined by the inner edge of the second upper surface 11C is referred to as an inner frame of the second upper surface 11C, and a frame defined by the outer edge of the second upper surface 11C is referred to as an outer frame of the second upper surface 11C.

The substrate 11 includes a recessed portion surrounded by the frame of the second upper surface 11C. The recessed portion defines a portion depressed down from the second upper surface 11C in the substrate 11. The first upper surface 11A is a part of the recessed portion. One or plural inner lateral surfaces 11E is a part of the recessed portion. The second upper surface 11C is located at a higher level than the first upper surface 11A.

The substrate 11 includes one or plural stepped portions 11F. The stepped portion 11F includes an upper surface 11G, and a lateral surface 11H that intersects the upper surface 11G and extends downwardly from the upper surface 11G. It is here understood that the surfaces that one stepped portion has are only one upper surface 11A and one lateral surface 11H. The upper surface 11G meets the inner lateral surface 11E. The lateral surface 11H meets the first upper surface 11A.

The one or each stepped portion 11F is provided inward of the inner frame of the second upper surface 11C in a top view. The one or each stepped portion 11F is formed along a portion or the whole of the inside surface 11E in a top view. In the substrate 11, the lateral surface 11H is an inner lateral surface, but is different from the inside surface 11E. The one or each inner lateral surface 11E, and the one or each lateral surface 11H is perpendicular to the first upper surface 11A. The term “perpendicular” allows a difference of ±3 degrees.

The one or each stepped portion 11F may include a first stepped portion 11F1 and a second stepped portion 11F2. The first stepped portion 11F1 and the second stepped portion 11F2 are provided in a position where their respective lateral surfaces 11H are opposite to each other. Each of the first stepped portion 11F1 and the second step 11F2 is arranged on a short-side side of the inner frame of the second upper surface 11C.

The one or plural inner lateral surfaces 11E may include first and second inner surfaces 11E1 and 11E2 opposite to each other. The first upper surface 11A is located between the first inner surface 11E1 and the second inner surface 11E2 in a top view. The first stepped portion 11F1 is provided closer to the first inner surface 11E1. The second stepped portion 11F2 is provided closer to the second inner surface 11E2.

The substrate 11 includes a base portion 11M and a frame portion 11N. The base portion 11M and the frame portion 11N may be formed of members different from each other. The substrate 11 may be formed in such a way as to include a substrate member corresponding to the base portion 11M and a frame member equivalent to the frame portion 11N.

The base portion 11M includes the first upper surface 11A. The frame portion 11N includes the second upper surface 11C. The frame portion 11N includes one or plural outer sides 11D and one or plural inner sides 11E. The frame portion 11N includes one or more stepped portions 11F.

The base portion 11M has a lower surface configured to form a portion or the whole of the lower surface 11B of the substrate 11. When the lower surface of the base portion 11M forms a certain area of the lower surface 11B of the substrate 11, the lower surface of the frame portion 11N forms the remaining area of the lower surface 11B of the substrate 11.

The substrate 11 includes a plurality of wiring portions 12A. The plurality of wiring portions 12A include one or plural first wirings 12A1 disposed within the internal space of the package 10, and one or plural second wirings 12A2 located on the outer surface of the package 10.

The one or each first wiring portion 12A1 is provided on the upper surface 11G of the stepped portion 11F. The substrate 11 includes one or plural first wiring portions 12A1 disposed on the upper surface 11G of the first stepped portion 11F1. The substrate 11 includes one or plural second wiring portions 12A1 disposed on the upper surface 11G of the second stepped portion 11F2.

The one or each second wiring portion 12A2 is located on the lower surface 11B of the package 10 The one or each second wiring portion 12A2 is located on the lower surface of the frame portion 11N. It is noted here that the second wiring portion 12A2 may be disposed on an outer surface different from the lower surface 11B of the package 10.

When divided into two areas by a virtual line passing through the lateral surface 11H of the second stepped portion 11F2 and parallel with that lateral surface 11H in a top view, the substrate 11 includes one or plural second wiring portions 12A2 provided on the lower surface 11B of the substrate 11 in an area including the upper surface 11G of the second stepped portion 11F2.

In the substrate 11, the one or each first wiring portion 12A1 is electrically connected to the second wiring portion 12A2. The one or plural first wiring portions 12A1 are electrically connected to the second wiring portions 12A2 different from one another.

The substrate 11 includes a joining pattern. The joining pattern is provided on the second upper surface 11C. The joining pattern is arranged in an annular shape. The joining pattern is arranged in a rectangular annular shape. In a top view, the first upper surface 11A is surrounded with the joining pattern.

For instance, the substrate 11 may be formed using a ceramic as the main material. The ceramic used as the main material of the substrate 11 typically includes aluminum nitride, silicon nitride, aluminum oxide, or silicon carbide.

It is here understood that the main material refers to a material having the highest volume ratio in the resulting product. However, when a member is formed of one material, that material is the main material. It follows that a certain material being a main material includes a case where the proportion occupied by that material can reach 100%.

The substrate 11 may be formed using a base member and a frame member composed of main materials different from one another. For instance, the base member may be formed by use of a main material with good heat dissipation property such as a metal, a metal-containing composite material, graphite, and diamond. The metal providing the main material of the base member, for instance, includes copper, aluminum, or iron. The metal-containing composite providing the main material of the base member includes copper molybdenum or copper tungsten as an example. The frame member may be formed using the ceramic mentioned above as the main material of the substrate 11 as a main material, for example.

For instance, the wiring portion 12A may be formed using a metal material as a main material. Examples of the metallic material for the main material of the wiring portions 12A may include a single metal such as Cu, Ag, Ni, Au, Ti, Pt, Pd, Cr, and W or an alloy containing them. For instance, the wiring portion 12A may also be formed of one or plural metal layers.

For instance, the joining pattern may be formed using a metallic material as a main material. Examples of the metallic material for the main material of the joining pattern may include a single metal such as Cu, Ag, Ni, Au, Sn, Ti, and Pd or an alloy containing them. For instance, the joining pattern may also be formed of one or plural metal layers.

The lid 14 has an upper surface 14A and a lower surface 14B. The lid 14 also has one or plural lateral surfaces 14C. The lid 14 is configured in a flat shape of a cuboid. It is noted here that the shape of the lid 14 does not have to be cuboidal.

The lid 14 is joined to the substrate 11. The lower surface 14B of the lid 14 is joined to the second upper surface 11C of the substrate 11. The lid 14 is joined to the joining pattern of the substrate 11. The lid 14 is joined to the substrate 11 via an adhesive.

The lid 14 is light transmissive. The term “light transmissive” means that the transmission of light entering the lid 14 and transmitting through the lid 14 is at least 80%. The lid 14 may have a non-transmitting area (without light transmissive).

For instance, the lid 14 may be formed using a glass as a main material. Alternatively, the lid 14 may be formed using sapphire as a main material.

### Light-emitting element 2

A light-emitting element 20 has an upper surface 21A, a lower surface 21B, and a plurality of lateral surfaces 21C. The upper surface 21A has a rectangular outer shape. This rectangular outer shape has a long side and a short side. In a top view, the light-emitting element 20 has a rectangular outer shape. This rectangular outer shape has a long side and a short side. The shape of the upper surface 21A and the outer shape of the light-emitting element 20 in a top view are not limited thereto.

The light-emitting element 20 has a light-emitting surface 22 capable of emitting light. For instance, the lateral surface 21C may be configured as the light-emitting surface 22. The lateral surface 21C configured as the light-emitting surface 22 meets the short side of the upper surface 21A. For instance, the upper surface 21A may serve as the light-emitting surface 22. The light-emitting element 20 has one or plural light-emitting surfaces 22.

For instance, a light-emitting element capable of emitting blue light may be utilized for the light-emitting element 20. For instance, a light-emitting element capable of emitting green light may be utilized for the light-emitting element 20. Typically, a light-emitting element capable of emitting red light may be used for the light-emitting element 20. It is noted here that any light-emitting element capable of emitting other colors may be used for the light-emitting element 20.

“Blue light” refers to light having a peak wavelength of emission within a range of 420 nm to 494 nm. Green light” refers to light having a peak wavelength of emission within a range of 495 nm to 570 nm. “Red light” refers to light having a peak wavelength of emission within a range of 605 nm to 750 nm.

A nitride semiconductor-containing light-emitting element for the light-emitting element 20 that emits blue light or green light. A GaN-based semiconductor such as GaN, InGaN, and AlGaN may be used as the nitride semiconductor. Examples of the light-emitting element 20 emitting red light may include a light-emitting element containing a semiconductor based on InAlGaP, GaInP, and GaAs such as GaAs or AlGaAs.

For instance, a semiconductor laser element may be utilized for the light-emitting element 20. A single emitter semiconductor laser element composed of a single emitter may be utilized for the light-emitting element 20. Alternatively, a multi-emitter semiconductor laser element composed of a plurality of emitters may be utilized for the light-emitting element 20. It is noted here that not only semiconductor laser elements but also light-emitting diodes may be utilized for the light-emitting element 20.

Reference is here made to a semiconductor laser element that is one example of the light-emitting element 20.

The semiconductor laser element gives out directional laser light. Expansive divergent light is emitted from a light emission surface of the semiconductor laser element. The light emitted from the semiconductor laser element forms an oval far field pattern (hereafter referred to as “FFP”) on a plane parallel with the light emission surface 22. “FFP” refers to the shape and light intensity distribution of emitted light at a location away from the light emission surface of the semiconductor laser element.

Here light passing through the center of the oval FFP shape or, in another terms, light having a peak intensity in the light intensity distribution of FFP is called light passing along or through an optical axis. In the light intensity distribution of FFP, light having an intensity of at least 1/e² relative to the peak intensity value is termed as light of the major portion.

The FFP shape of light emitted from the semiconductor laser element is an oblong shape wherein, as viewed on a plane parallel with the light-emitting surface 22, the layering direction is longer than a perpendicular direction perpendicular to the layering direction. The lamination direction refers to a direction wherein a plurality of semiconductor layers inclusive of an active layer are stacked or laminated one upon another as viewed in the semiconductor laser element. A direction perpendicular to the layering direction may also be called a planar direction of the semiconductor layer. The long axis direction and the short axis direction of the FFP oval shape may respectively be called the fast axis direction and the late axis direction.

An angle at which light having a light intensity of 1/e² of the peak light intensity spreads as based on the FFP light intensity distribution is defined as the angle of light spread. The angle of light spread herein is defined as an angle at which light having the peak light intensity (passing through the optical axis) makes with light having a light intensity of 1/e² of the peak light intensity. The angle of light spread is sometimes found from, in addition to the light intensity of 1/e² of the peak light intensity, a light intensity half of the peak light intensity. In the present disclosure, mere reference to the “angle of light spread” refers to the angle of light spread at a light intensity of 1/e² of the peak light intensity.

### Sub-Mount 30

A sub-mount 30 includes an upper surface 31A, a lower surface 31B, and one or plural lateral surfaces 31C. The upper surface 31A may be called the mounting surface on which other components are to be mounted. The upper surface 31A may be provided in a rectangular shape. This rectangular shape of the upper surface 31A may include a short side and a long side. It is noted here that the upper surface 31A is not limited to the rectangular shape.

The sub-mount 30 has an outer rectangular shape in a top view. This rectangular shape of the sub-mount 30 may include a short side and a long side. It is noted here that the sub-mount 30 outer shape is not limited to the rectangular shape in a top view. In a top view, the sub-mount 30 may have an outer shape in which one direction (hereafter called the widthwise direction of the sub-mount 30) has a length shorter than the length of a direction perpendicular thereto (hereafter called the lengthwise direction). In the sub-mount 30 shown, the widthwise direction is the same as the X-direction and the lengthwise direction is the same as the Y-direction.

The length of the sub-mount 30 in the short-side direction or widthwise direction is in a range of 500 μm to 1000 μm, for example. The length of the sub-mount 30 in the long-side or lengthwise direction is in a range of 1500 to 2500 μm, for example. There is a difference in length in a range of 500 μm to 1000 μm between the lengthwise direction and the widthwise direction.

### Reflection Member 40

A reflection member 40 has a lower surface 41A, and a light reflection surface 41B. The light reflection surface 41B inclines relative to the lower surface 41A. A straight line connecting the lower end and upper end of the light reflection surface 41B also inclines relative to the lower surface 41A. An angle at which the light reflection surface 41B inclines relative to the lower surface 41A is now called an angle of inclination of the light reflection surface 41B.

The light reflection surface 41B is defined by a plane. It is noted here that the light reflection surface 41B may be defined by a curved surface. The angle of inclination of the light reflection surface 41B is 45 degrees. Although the angle of inclination of the light reflection surface 41B is not limited thereto.

A glass, metal or the like may be utilized as the main material of the reflection member 40. Preferably, a material resistant to heat is used for the main material of the reflection member 40. For instance, a glass such as quartz or BK7 (borosilicate glass) or a metal such as Al may be used for the main material. Alternatively, the reflection member 40 may be formed using Si as the main material.

If the main material is provided by a reflective material such as Al, it is then possible to form the light reflection surface 41B out of the main material. Instead of forming the light reflection surface 41B by the main material, it is possible to form a preliminary shape of the reflection member 40 and form the light reflection surface 41B on the surface of this preliminary shape. In this case, the light reflection surface 41B may be formed using a metal layer such as Ag, and Al or a dielectric multi-layer such as Ta₂O₅/SiO₂, TiO₂/SiO₂, and Nb₂O₅/SiO₂.

The light reflection surface 41B has a reflectivity of 90% or higher relative to the peak wavelength of light irradiated on the light reflection surface 41B. The reflectivity may be 95% or more. It is also possible to set this reflectivity to 99% or more. Thus, the light reflectivity may be no more than or below 100%.

### Wirings 60

The wiring 60 is defined by an electrically conductive linear material having joining portions at both ends. The joining portions at both ends provide portions to be joined to other component. The wiring 60 is used for providing an electrical connection between two components. One typical example of the wiring 60 is a metal wire. For instance, gold, aluminum, silver, and copper may be used for the metal.

### Optical Member 70

The optical member 70 has an upper surface 71A, a lower surface 71B, and one or plural sides 71C. The optical member 70 provides an optical action to light incident thereon. The optical actions provided by the optical member 70 to incident light typically include concentration, collimation, diffusion, polarization, diffraction, multiplexing, guiding, reflection, and wavelength conversion, of light.

The optical member 70 includes an optical action surface capable of optical actions. The upper surface 71A, lower surface 71B, or lateral surface 71C may serve as an optical action surface. Alternatively, this optical member 70 may have an optical action surface at a location different from the upper surface 71A, lower surface 71B, and lateral surface 71C. Typically, the optical action surface may be formed within the optical member 70 rather than on the surface thereof.

The optical member 70 may include one or plural lens surfaces 71D. The one or plural lens surfaces 71D serve as the optical action surface of the optical member 70. It is noted here that the optical member 70 having the lens surface 71D may be called a lens member. Optical actions such as concentration of light, diffusion, or collimation are given by the optical member 70 to light passing through the lens surface 71D and exiting the optical member 70. For instance, the optical member 70 may be a collimating lens for conversion of light incident on the optical member 70 to collimated light that then exits.

The optical member 70 has an outer rectangular shape in a top view. It is noted here that the outer shape of the optical member 70 is not limited to any rectangular one. The lower surface 71B is defined by a plane. The lens surface 71D is not formed on the lower surface 71B side of the optical member 70. The lower surface 71B is in a rectangular shape. It is here understood that the shape of the lower surface 71B is not limited to a rectangular shape.

The optical member 70 may comprise a plurality of lens surfaces 71D aligned in one direction. The direction in which the plural lens surfaces 71D are aligned is here called the lens link direction in a top view. In the optical member 70 shown, the lens link direction is the same as the X direction.

The plurality of lens surfaces 71D are formed such that their apexes are arranged in one straight line. This virtual straight line connecting the respective apexes is parallel with the lower surface 71B of the optical member 70. It is noted here that such parallel arrangement includes a tolerance of the order of ±5 degrees.

The optical member 70 is light transmissive. The optical member 70 has a transmittance of 80% or more relative to the peak wavelength of light incident thereon. The optical member 70 may comprise a light transmissive area and a non-light transmissive area (hereafter called the opaque area). The non-light transmissive area has a transmittance of 50% or less relative to the peak wavelength of light incident on the optical member 70. The optical member 70 may be formed using a glass such as BK7 as an example.

Then, the light-emitting device 1 will be explained.

### Light-emitting device 1

Referring to the light-emitting device 1, one or plural light-emitting elements 20 are located on a substrate 11. The one or plural light-emitting elements 20 are disposed on the first upper surface 11A. The light-emitting device 1 is configured to emit light from the one or plural light-emitting elements 20.

The one or respective light-emitting elements 20 are configured to emit light in the widthwise direction of the substrate 11. It is noted here that in the light-emitting device 1 shown, the widthwise direction of the substrate 11 is the same as the short-side direction of the substrate 11; however, the term “widthwise direction” is here used because the outer edge shape of the substrate 11 is not limited to a rectangular shape. The same is also true of the “lengthwise direction” of the substrate 11.

The one or plural light-emitting elements 20 may be composed of a plurality of light-emitting elements 20. The one or plural light-emitting elements may be composed of a plurality of light-emitting elements 20 including one or plural first light-emitting elements 20A, and one or plural second light-emitting elements 20B. The plurality of light-emitting elements 20 may further include one or plural third light-emitting elements 20C.

In the light-emitting device 1, the one or plural first light-emitting elements 20A are configured to emit light having a first color. The one or plural second light-emitting elements 20B are configured to emit light having a second color. The one or plural third light-emitting elements 20C are configured to emit light having a third color. The first, second, and third colors are different from one another.

In the example shown in FIG. 12, the light-emitting device 1 includes a first light-emitting element 20A configured to emit red light as the first color, a second light-emitting element 20B configured to emit green light as a second color, and a third light-emitting element 20C configured to emit blue light as a third color.

A plurality of light-emitting elements 20 are arranged and located in one direction. In the light-emitting device 1 shown, this direction is the same as the X direction. In the light-emitting device 1, a plurality of light-emitting elements 20 are arranged and located in the lengthwise direction of the substrate 11.

The one or plural light-emitting elements 20 are located between two first wiring portions 12A1 in a top view. The one or plural light-emitting elements 20 are sandwiched between the two first wiring portions 12A1 in the lengthwise direction of the substrate 11. The slow axis direction of light emitted from the one or respective light-emitting elements 20 is the same as the lengthwise direction of the substrate 11.

The one or plural light-emitting elements 20 are disposed on one or plural sub-mounts 30. The one or plural light-emitting elements 20 are disposed on the substrate 11 via the one or plural sub-mounts 30. The one or plural sub-mounts 30 are provided with one light-emitting element 20.

In the light-emitting device 1, one or plural reflection members 40 are disposed on the substrate 11. The one or plural reflection members 40 are disposed on the first upper surface 11A. The one or plural reflection members 40 are disposed at locations away from the one or plural light-emitting elements 20 in a direction perpendicular to a light emission surface 22. The one or plural reflection members 40 are configured to reflect light from the one or plural light-emitting elements 20. The light reflected off by the one or plural reflection members 40 travels upward. In the FFP of the reflected light, the lengthwise direction of the substrate 11 defines the slow axis direction, and the widthwise direction defines the fast axis direction.

When the light-emitting device 1 includes plural light-emitting elements 20, the position where the axis of light emitted from each light-emitting element 20 is irradiated by the corresponding one of the one or plural reflection members 40 is located on one straight line in a top view. Arranging light axis irradiation points on one straight line makes optical control easier.

In the light-emitting device 1, a plurality of wirings 60 are used for electrical connection of the one or plural light-emitting elements 20. A suitable number of wirings 60 are joined to the package 10, light-emitting elements 20, or sub-mount 30 so that the one or plural light-emitting elements 20 can be electrically connected to the package 10. Accordingly, power from an external power source electrically connected to the package 10 can be supplied to the one or plural light-emitting elements 20 disposed within the internal space of the package 10.

The wiring(s) 60 joined to the package 10 is also joined to a wiring portion 12A disposed within the internal space of the package 10. The plurality of wirings 60 include one or plural wirings 60 joining to a first wiring portion 12A1 located on the first inner surface 11E1 side, and one or plural wirings 60 joining to a first wiring portion 12A1 located on the second inner surface 11E2 side. The one or plural light-emitting elements 20 connect electrically to the first wiring portion 12A1 of the substrate 11. The first and second inner surfaces 11E1 and 11E2 are opposite to each other in the lengthwise direction of the substrate 11.

In the light-emitting device 1, light emitted from the one or plural light-emitting elements 20 exits the upper surface 14A of the package 10. Here the light emitted from the light-emitting element 20 is defined by a ”light-per-element” unit. Light having one light-per-element unit is emitted from one light-emitting element 20 whereas light having a plurality of light-per-element units are emitted from a plurality of light-emitting elements 20.

A major portion of light having a light-per-element unit emitted from a certain light-emitting element 20 is not overlapped on a major portion of light having a light-per-element unit emitted from another light-emitting element 20 on the upper surface 14A. Light having a light-per-element unit is incident on the upper surface 14A and exits the upper surface 14A without superimposing the respective major portions on one another.

In the light-emitting device 1, the optical member 70 is fixed to the package 10. The optical member 70 is connected to the package 10. The optical member 70 is joined to the package 10 via an adhesive. An ultraviolet curing adhesive may typically be used for the optical member 70.

The optical member 70 is located above the package 10. Light emitted from the upper surface 14A is incident on the optical member 70, undergoes optical action, and then exits the optical member 70. For instance, the light is incident on lens surfaces having optical axes of light-per-element units different from one another where it is collimated, exiting the optical member 70.

### Wiring Board 101

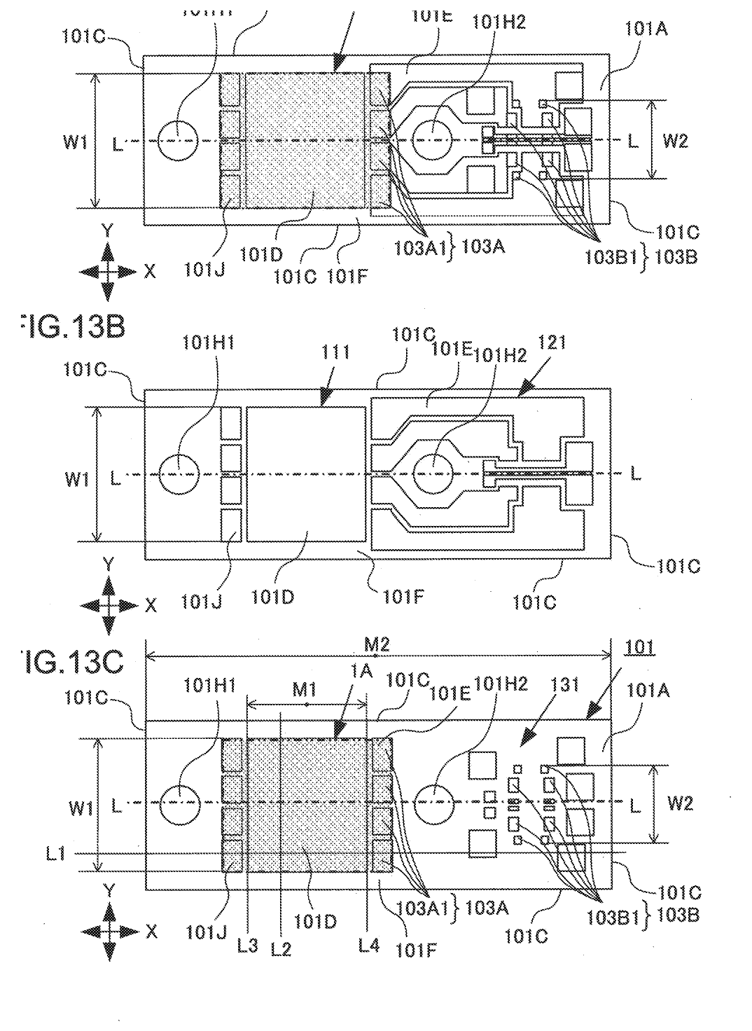

The wiring board 101 according to an embodiment of the invention will now be explained. FIG. 13A, 13B, 13C are illustrative of an exemplary embodiment of the wiring board 101; FIG. 13A shows that the upper view of the wiring board 101 according to an embodiment and a wiring pattern are imposed one upon another; FIG. 13B is indicative of a wiring pattern on the wiring board 101 according to an embodiment; and FIG. 13C is an upper view of the wiring board 101 according to an embodiment.

The wiring board 101 has an upper surface 101A, a lower surface 101B, and one or plural lateral surfaces 101C. The wiring board 101 has a plate-like shape. In a top view, the outer edge of the wiring board 101 is in a rectangular shape that may include a long side and a short side.

The wiring board 101 is provided with one or plural fixing through-holes 101H. The one or plural fixing through-holes 101H include a through-hole 101H configured to fix the wiring board 101 to another member (component). For instance, the through-hole 101H is provided for the purpose of fixation with screws; a screw is fitted in the through-hole 101H to fix the wiring board 101 to another member.

The one or plural through-holes 101H include a first fixing portion 101H1 for fixing the wiring board 101 in place and a second fixing portion 101H2 for fixing the wiring board 101 in place. The first screw 102A is fixedly threaded through the first fixing portion 101H1 and the second screw 102B is fixedly threaded through the second fixing portion 101H2 to fix the wiring board 10 to another member.

The wiring board 101 includes a heat dissipation portion 101D, an electrode portion 101E, and an insulation portion 101F. The heat dissipation portion 101D functions as a heat dissipation path for heat generated from another component mounted on the wiring board 101. The electrode portion 101E is configured to make an electrical connection to another component mounted on the wiring board 101.

The insulation portion 101F is configured to make insulation between the heat dissipation portion 101D and the electrode portion 101E. The insulation portion 101F is provided on the wiring board 101 to insulate electrical connection between the heat dissipation portion 101D and the electrode portion 101E.

On the upper surface 101A of the wiring board 101, there are an area where the heat dissipation portion 101D is in the uppermost position (hereafter called the heat dissipation area of the upper surface 101A), an area where the electrode portion 101E is in the uppermost position (hereafter called the electrode area of the upper surface 101A), and an area where the insulation portion 101F is in the uppermost position (hereafter called the insulation area of the upper surface 101A). On the upper surface 101A, the heat dissipation area and the electrode area are isolated by the insulation area.

The wiring board 101 comprises a heat dissipation member 111, a plurality of electrode members 121, and an insulation member 131. The heat dissipation portion 101D includes the heat dissipation member 111; the electrode portion 101E includes a plurality of electrode members 121; and the insulation portion 101F includes the insulation member 131.

The wiring board 101 has a mounting surface including a first area 1A, and the upper surface 101A of the wiring board 101 may provide a mounting surface. The heat dissipation area and electrode area are exposed from the insulation member 131 disposed on the mounting surface. The first area 1A includes the electrode area. The first area 1A includes the heat dissipation area. The first area 1A includes the insulation area.

A portion of the electrode portion 101E which, in a top view (viewed from the plane in a direction perpendicular to the mounting surface), overlaps on the electrode area included in the first area 1A is here called the first electrode portion 103A. A portion of the electrode portion 101E which overlaps on an electrode area configured to be electrically connected to the first electrode portion 103A and located outside of the first area 1A is here called as the second electrode portion 103B.

A plurality of electrode members 121 include an electrode member 121 having the first and second electrode portions 103A and 103B. In short, a portion of one electrode member 121 may provide the first electrode portion 103A while at least another portion may provide the second electrode portion 103B.

The first electrode portion 103A includes two or more electrode members 121. Each electrode member 121 is partially included in the second electrode portion 103A. The electrode area included in the first electrode 103A may be divided into a plurality of the first electrode area 103A1 arranged and located in one direction. The first electrode portion 103A includes a plurality of first electrode areas 103A1 which are not electrically connected to one another. On the wiring board 101 shown, a plurality of the first electrode areas 103A1 are aligned in the Y direction.

The second electrode portion 103B includes two or more electrode members 121. Each electrode member 121 is partially included in the second electrode portion 103B. The electrode area included in the second electrode 103B may be divided into a plurality of the second electrode area 103B1. The second electrode portion 103B includes a plurality of second electrode areas 103B1 which are not electrically connected to one another.

As viewed in the alignment direction of a plurality of the first electrode areas 103A1, the length W1 of the first electrode portion 103A from one end to the opposite end is larger than the length W2 of the second electrode portion 103B from one end to the opposite end in the same direction. It is noted here that the length W1 of the first electrode portion 103A from the one end to the opposite end is the lengths W1 at both outer side ends of the two first electrode areas 103A1 positioned on the outermost sides in the same direction. Likewise, the length W2 of the second electrode portion 103B from one end to the opposite end is the length W2 at both outer side ends of the two second electrode areas 103B1 positioned on the outermost sides in the same direction.

The wiring board 101 may further include a joining portion 101J that is included in the first area 1A in a top view. In a top view, the heat dissipation area is located between the joining portion 101J and the first electrode portion 103A. The joining portion 101J is located at a position separated from the first electrode portion 103A in the long-side direction of the wiring board 101. In a top view, a virtual straight line L1 parallel with this long-side direction passes through the joining portion 101J, the heat dissipation area, and the first electrode portion 103A. In a top view, the joining portion 101J may have the same shape as the first electrode portion 103A. The joining portion 101J is not electrically connected to the electrode portion 101E.

In a top view, a virtual straight line L2 through both ends of the heat dissipation area in the short-side direction of the wiring board 101 does not pass through the electrode area. In a top view, the first electrode portion 103A and joining portion 101J are located in a position where the virtual straight line L2 does not pass. In a top view, the electrode portion 101E located in a position where the virtual straight line L2 does not pass. This is in turn helpful to reduce the width of the wiring board 101 in the short-side direction.

In a top view, the upper surface 101A of the wiring board 101 is divided by a virtual straight line L3 and a virtual straight line L4 into three areas: a first end area, a second end area, and a central area interposed between the first and the second end areas in a top view. The virtual straight line L3 passes through or coincides with one of two ends of the heat dissipation area in the long-side direction of the wiring board 101 in the top view. The virtual straight line L4 passes through or coincides with the other end of the heat dissipation area in the top view. Both of these ends of the heat dissipation area extend parallel with the short-side direction of the wiring board 101. Both of the virtual straight lines L3 and L4 extend across the long-side direction of the wiring board 101. In all the electrode members 121 that the wiring board 101 have, there is then no electrode member having a link from the first end area to the second end area via the central area. This can reduce the width of the wiring board 101 in the short-side direction.

With respect to the long-side direction of the wiring board 101 in a top view, a midpoint M1 of the length of the heat dissipation area is positioned closer to the joining portion 101J than a midpoint M2 of the width of the upper surface 101A. It is noted here that “closer to the joining portion 101J” means a direction from the heat dissipation area toward the joining portion 101J while a direction from the heat dissipation area toward the first electrode portion 103A is called the first electrode portion 103A side. In any case, “closer to the joining portion 101J” and “closer to the first electrode portion 103A” may define a direction parallel with the long-side direction of the wiring board 101.

In a top view, the second electrode portion 103B is positioned closer to the first electrode 103A rather than the midpoint M2, and in a top view, the first electrode portion 103A is disposed between the joining portion 101J and the second electrode portion 103B.

In a top view, the first area 1A is located between a first fixing portion 101H1 and a second fixing portion 101H2 in the wiring board 101. In a top view, the second fixing portion 101H2 is located between the first electrode portion 103A and the second electrode portion 103B. In a top view, the heat dissipation area is located between the fixing portion 101H1 and the first electrode 103A. In a top view, the joining portion 101J is located between the first fixing portion 101H1 and the heat dissipation area.

In a top view, the first fixing portion 101H1, first area 1A, second fixing portion 101H2, and second electrode portion 103B are aligned in order in the long-side direction of the wiring board 101. In a top view, the virtual linear line L parallel with the first direction X passes through the light-emitting device 1, first fixing portion 101H1, second fixing portion 101H2, and second electrode portion 103B. In a top view, the virtual linear line L may be a straight line passing through the midpoint of the width in the short-side direction of the wiring board 101.

The first fixing portion 101H1 is located at a position distant from the midpoint M1 by a given distance in the long-side direction, and the second fixing portion 101H2 is located at a position distant from the midpoint M1 by the same distance in an opposite direction. As referred to herein, the “long-side direction” corresponds to the negative X direction in the light-emitting module 901 shown in the figure(s), and the “opposite direction” corresponds to the positive X direction in the light-emitting module 901 shown.

Regarding the long-side direction of the wiring board 101, the length of the wiring board 101 may be 1.4 times to 3 times as much as the distance from the fixing portion 101H1 to the second fixing portion 101H2. Being 1.4 times as much makes it easy to ensure an area where the second electrode portion 103B is located, and being less than 3 times as much makes it possible to reduce the length of the wiring board 101 in the long-side direction.

In a top view, if a virtual straight line passing through the midpoint M2 and parallel with the short-side direction of the wiring board 101 is used to divide the upper surface 101A into two areas, it is then possible to locate the first fixing portion 101H1 in one area and the second fixing portion 101H2 in another area. The first fixing portion 101H1 is located closer to the joining portion 101J from the midpoint M2, and the second fixing portion 101H2 is located closer to the first electrode 103A from the midpoint M2. Such provision of the first 101H1 and second fixing portion 101H2 can aid in reducing the length of the wiring board 101 in the long-side direction.

A metal material is used as the main material for the heat dissipation member 11. For instance, a single metal such as Cu, Ag, Al, Ni, Rh, Au, Ti, Pt, Pd, Mo, Cr, and W or an alloy containing such metals may be used as the main material for the heat dissipation member 111. Preferably, the heat dissipation member 111 is formed of a material with good heat dissipation property. The heat dissipation member 111 could be formed with the inclusion of 95 wt.% or more copper.

A metal material is used as the main material for the electrode member 121. For instance, a single metal such as Cu, Ag, Al, Ni, Rh, Au, Ti, Pt, Pd, Mo, Cr, and W or an alloy containing such metals may be used as the main material for the electrode member 121.

The insulation member 131 is formed of an insulation material. For instance, a polyimide may be used as the main material for the insulation member 131. Alternatively, a glass epoxy obtained by impregnating the main material comprising one or plural glass cloths with a thermosetting insulation resin such as an epoxy resin, followed by curing of this thermosetting insulation resin, a liquid crystal polymer or the like may be used as the main material for the insulation member 131. Still alternatively, a resist such as solder resist may be used for the insulation member.

### Connector 201

A connector 201 is a typical connecting member useful for electrical connection. By use of the connector 201, it is possible to insert a wiring terminal into the connector 201 for electrical connection thereto.

The connector 201 shown in the figure(s) has an upward insertion port configured to receive a wiring terminal. The terminal linking to the insertion port extends in a planar direction with a lower surface side providing a joining surface configured to join the terminal to other components. The insertion port may be sideward rather than upward.

In a top view, the connector 201 has an outer shape wherein the length of one direction is larger than the length of a direction perpendicular thereto. Herein “one direction” is defined as the lengthwise direction of the connector 201, and “another direction” as the widthwise direction of the connector 201. In the connector 201 shown in the figure(s), the widthwise direction is identical to the X direction, and the lengthwise direction is identical to the Y direction.

### Thermistor 301

The thermistor 301 may be used as a temperature measuring element. The thermistor 301 is one example of the temperature measuring element configured to measure a temperature.

The light-emitting module 901 is now explained.

### Light-Emitting Module 901

In the light-emitting module 901, the light-emitting device 1 is mounted on the wiring board 101. The light-emitting device 1 is mounted in the first area 1A of the wiring board 101. The light-emitting device 1 is mounted on the wiring board 101 such that the lengthwise direction of the substrate 11 in the light-emitting device 1 is identical to the lengthwise direction of the wiring board 101. This enables the reduction of the width of the wiring board 101 in the widthwise direction, contributing more to size reduction of the light-emitting module 901. In the light-emitting module 901 shown in the figure(s), the lengthwise direction of the wiring board 101 is identical to the long-side direction, and the widthwise direction is identical to the short-side direction.

Herein, the lengthwise direction of the wiring board 101 is defined as a first direction, and the widthwise direction of the wiring board 101 is defined as a second direction. The lengthwise and widthwise directions of the substrate 11 could be the first direction and the second direction, respectively. In the light-emitting module 901 shown in the figure(s), the first direction is the same as the X direction and the second direction is the same as the Y direction.

The first electrode portion 103A of the wiring board 101 is joined with the substrate 11 in the light-emitting device 1. The first electrode portion 103A is electrically connected to the substrate 11 in the light-emitting device 1, and to one or plural light-emitting elements 20.

The first electrode portion 103A is joined to the second wiring portion 12A2 of the substrate 11. The first electrode portion 103A is joined to the second wiring portion 12A2 located on the first inner surface 11E1 of the substrate 11.

The first electrode portion 103A is joined to one of the second wiring portions 12A2 that is electrically connected to the first wiring portion 12A1 electrically connected to the light-emitting element 20 and located on the first inner surface 11E1 side, and to another one of the second wiring portions 12A2 that is electrically connected to the first wiring portion 12A1 electrically connected to the light-emitting element 20 and located on the second inner surface 11E2 side. A plurality of the first electrode areas 103A1 are each joined to the corresponding one of the second wiring portions 12A2.

The joining portion 101J of the wiring board 101 is joined with the substrate 11 in the light-emitting device 1. The joining portion 101J is joined with the second wiring portion 12A2 of the substrate 11. The joining portion 101J is also joined to the second wiring portion 12A2 located on the second inner surface 11E2 side of the substrate 11. The joining portion 101J may be joined to a joining portion alternative to the second wiring portion 12A2. In short, the portion of the substrate 11 to be joined to the joining portion 101J does not need to be defined by a portion electrically connected to the first wiring portion 12A1.

A current path for supplying power to the one or plural light-emitting elements 20 is formed by the first electrode portion 103A. The joining portion 101J takes no direct part in the formation of the current path for supplying power to the one or plural light-emitting elements 20. In short, the light-emitting device 1 does not need to be electrically connected to the joining portion 101; if the light-emitting device 1 is electrically connected to the first electrode portion 103A, power can be supplied thereto from the outside. This contributes more to size reductions of the wiring board 101.

A plurality of the first electrode areas 103A1 include two first electrode areas 103A1 which form a current path for supplying power to the one or plural first light-emitting elements 20A. A plurality of the first electrode areas 103A1 include two first electrode areas 103A1 which form a current path for supplying power to the one or plural second light-emitting elements 20B. One of the two electrodes that each of the first light-emitting element 20A and the second light-emitting element 20B has may be electrically connected to the same first electrode area 103A1. In this case, power may be supplied by three first electrode areas 103A1 to the first light-emitting element 20A and the second light-emitting element 20B.

A plurality of the first electrode areas 103A1 include two first electrode areas 103A1 which form a current path for supplying power to the one or plural third light-emitting elements 20C. It is noted here that one of the two electrodes that each of the first light-emitting element 20A, the second light-emitting element 20B, and the third light-emitting element 20C has may be electrically connected to the same first electrode area 103A1. In this case, power may be supplied by four first electrode areas 103A1 to the first light-emitting element 20A, the second light-emitting element 20B, and the third light-emitting element 20C.

The heat dissipation area of the wiring board 101 is joined with the substrate 11 in the light-emitting device 1. The heat dissipation area of the wiring board 101 is joined to the base portion 11M of the substrate 11, and the first electrode portion 103A and the joining portion 101J are joined to the frame 11N. The joining of the base portion 11M to the heat dissipation area enables heat generated from the one or plural light-emitting elements 20 located on the first upper surface 11A to dissipate.

In a top view, the first fixing portion 101H1 is located at a position distant from the light-emitting device 1 by a given distance in the lengthwise direction of the wiring board 101, and the second fixing portion 101H2 is located at a position distant from the light-emitting device 1 by the same distance in the opposite direction. Equalizing the distances from the light-emitting device, for instance, contributes more to the heat dissipation effect of the light-emitting device 1 when the wiring board 101 is fixed to a heat sink.

In the light-emitting module 901, the connector 201 is mounted on the wiring board 101. The connector 201 is joined to the second electrode portion 103B whereby the connector 201 is electrically connected to the light-emitting device 1. The connector 201 is electrically connected to an external power source, and used for supplying power from the external power source to the light-emitting device 1. The connector 201 may be called a connecting member for electrical connection of the one or plural light-emitting elements 20 to the outside.

In the light-emitting module 901, the connector 201 is mounted on the wiring board 101 such that the lengthwise direction of the connector 201 is along a second direction and the widthwise direction of the connector 201 is along a first direction. The length of the connector 201 in the lengthwise direction is smaller than the length of the light-emitting device 1 so that even when the connector 201 is mounted on the wiring board 101, the width of the wiring board 101 does not increase in the widthwise direction while the length decrease in the lengthwise direction.

In the light-emitting module 901, the length of the wiring board 101 in the second direction is greater than 100% or 150% or less of the length of the light-emitting device 1. When a plurality of the light-emitting modules 901 are aligned and arranged in the second direction, it is possible to make the interval(s) of the respective light-emitting devices 1 shorter in the second direction. There are also additional advantages expectable such as making individual drive control easy due to separation of the light-emitting modules 901 per unit and making the number of the light-emitting devices 1 easily adjustable.

In a top view, the second fixing portion 101H2 is disposed between the light-emitting device 1 and the connector 201. For instance, when a wire linking to an external power source extends from a wiring terminal inserted into the insertion port of the connector 201, there is one possibility of extending the wire from the connector 201 to the first electrode portion 103A side (the positive X direction in the drawing). However, the second fixing portion 101H2 is located from the connector 201 into the joining portion 101J side (the negative X direction in the drawing) so that a risk of contact of a screw fixed in the second fixing portion 101H2 with the wire is eliminated or reduced. Thus, the light-emitting module 901 is achievable while taking capability of mounting wirings on the light-emitting module 901 in consideration.

In the light-emitting module 901, the thermistor 301 is mounted on the wiring board 101. The thermistor 301 is mounted on the upper surface 101A of the wiring board 101. The thermistor 301 is joined to the electrode portion 101E. The electrode portion 101E to which the thermistor 301 is joined is electrically connected to the second electrode portion 103B. A plurality of the electrode members 121 include an electrode member 121 to which the thermistor 301 and connector 201 are joined.

In the light-emitting module 901, the thermistor 301 may be utilized to measure the temperature of the light-emitting device 1. The thermistor 301 may also be utilized to check the temperature environment of the light-emitting element 20 which is included in the light-emitting device 1. The “temperature environment of the light-emitting element 20” means, in addition to precise temperatures of the light-emitting element 20, whether or not the temperature of the light-emitting element 20 is higher than that in non-driving states, to what degrees temperatures rise, or the like.

In a top view, the thermistor 301 is disposed between the second fixing portion 101H2 and the second electrode portion 103B. In a top view, the second fixing portion 101H2 is disposed between the thermistor 301 and the light-emitting device 1. When it is utilized to measure the temperature of the light-emitting device 1, the thermistor 301 is preferably located as close to the light-emitting device 1 as possible. However, because the electrode portion 101E joined to the thermistor 301 is linked to the second electrode portion 103B, it is desired to configure the thermistor 301 as described above, helping to reduce the width of the wiring board 101 in the widthwise direction and, hence, contributing more to size reductions of the light-emitting module 901.

The distance from the thermistor 301 to the light-emitting device 1 is preferably 10 mm or less in a top view. By setting this distance at 10 mm or less, the thermistor 301 may be arranged in such a way to check the temperature environment of the light-emitting device 1 or light-emitting element 20 without any hitch. This distance is greater than the length of the second fixing portion 101H2 in the first direction.

In the light-emitting module 901, the first fixing portion 101H1, light-emitting device 1, second fixing portion 101H2, and connector 201 are located or provided in a position through which the virtual straight line L passes in a top view. The thermistor 301 is also located in a position through which the virtual straight line L passes in a top view.

### Other Embodiments

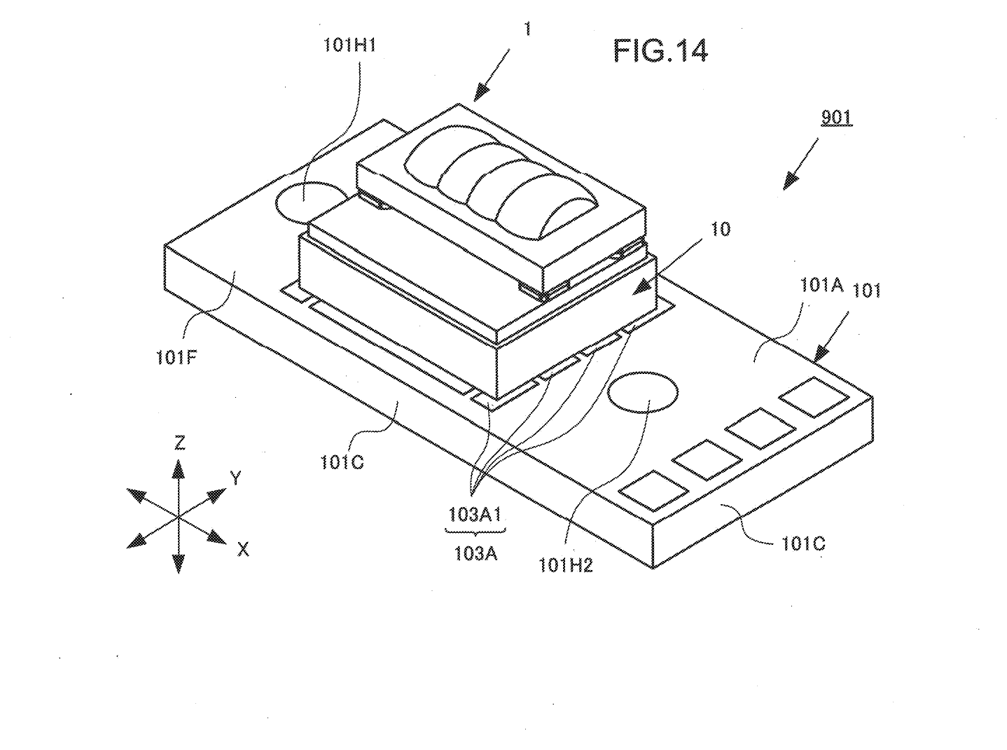

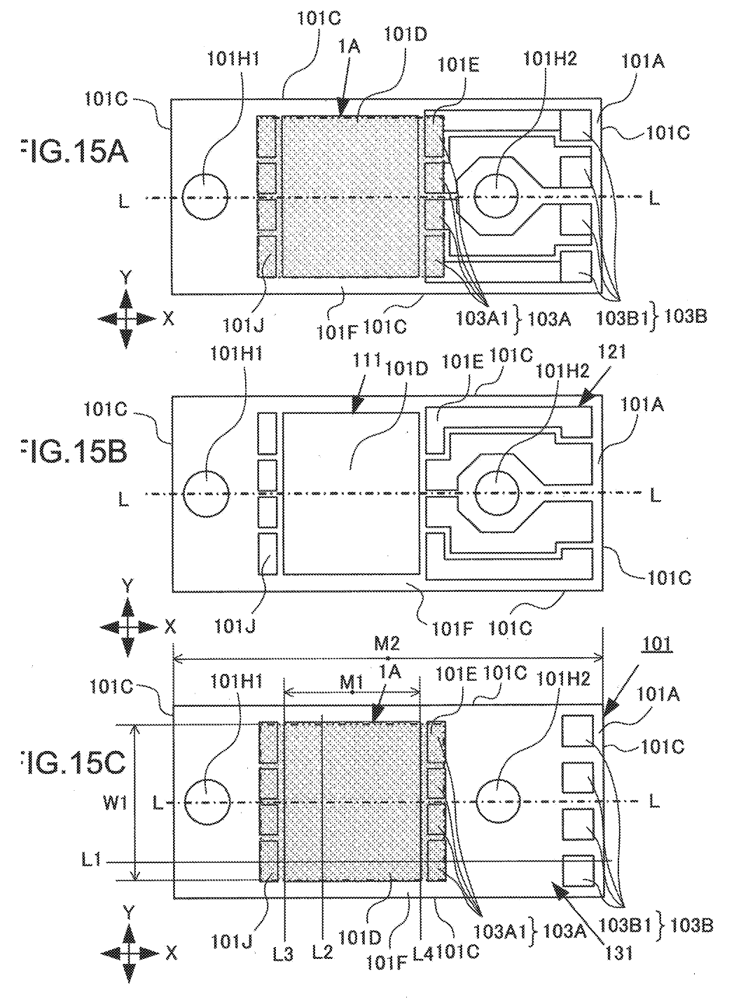

Some other embodiments of the light-emitting module 901 are now explained. FIG. 14 is a perspective view of a light-emitting module 901 according to another embodiment. FIG. 15A shows an overlap of a wiring pattern on the top view of the wiring board 101 according to another embodiment. FIG. 15B is a top view of the wiring board 101 according to another embodiment. FIG. 15C is illustrative of a wiring pattern of the wiring board 101 according to another embodiment. Hereafter, the light-emitting module 901 according to another embodiment will be called the second light-emitting module for the sake of convenience.

The second light-emitting module comprises a light-emitting device 1 and a wiring board 101. The second light-emitting module comprises neither connector nor thermistor used. The second light-emitting module is not required to be devoid of connectors and thermistors. The second light-emitting module may comprise a wire or like member as a connecting member in place of the connector. Other configurations may be the same as or similar to the embodiment shown in FIG. 1.

As the second light-emitting module does not comprise any thermistor, it is possible to reduce the length of the wiring board 101 in the lengthwise direction. In the second light-emitting module, too, the aforesaid contact risk may be avoided or eliminated, because the second fixing portion 101H2 is disposed between the first electrode portion 103A to which the light-emitting device 1 is joined and the second electrode portion 103B to which a wire is joined as a connecting member. By doing so, it is possible to embody the light-emitting module 901 while typically taking capability of mounting a connecting member on the wiring board 101 in consideration.

While some embodiments according to the present invention have been explained, it is understood that the light-emitting module 901 according to the present invention is not strictly limited to the light-emitting device 1 according to the respective embodiments. In short, the present invention is achievable without being limited to the outer shape and structure of the light-emitting module 901 disclosed herein. The present invention is achievable without using all the elements or components as essential requirements. For instance, even when a part of the elements or components for the light-emitting module 901 disclosed in the embodiments is not described in the scope of claims, the inventions described in those claims are specifically applicable to that part on the conditions that replacements, omissions, shape variations, and material variations are within freedom of design by a person in the art.

The light-emitting device 1 set forth in some embodiments may be applied to projectors. In other words, the projector may be called one usage to which the present invention is applied. It is noted here that the present invention may further be utilized in various usages such as lighting, exposure, vehicle-mounted headlights, head mounted displays, and other display headlights.

Semiconductor laser element

What is claimed is:

1. A light-emitting module comprising:
a light-emitting device including a plurality of semiconductor laser elements and a substrate on which the plurality of semiconductor laser elements are arranged along a longitudinal direction of the substrate; and
a wiring board having a mounting surface including a first area on which the light-emitting device is mounted, the wiring board having a longitudinal direction extending in a first direction and a widthwise direction extending in a second direction perpendicular to the first direction in a top view that is viewed from a direction perpendicular to the mounting surface, wherein
the wiring board includes
a first fixing portion and a second fixing portion at which the wiring board is configured to be fixed in place,
a first electrode portion to which the substrate is joined for electrical connection to the plurality of semiconductor laser elements, and
a second electrode portion electrically connected to the first electrode portion, the second electrode portion being configured to be connected to a connecting member for electrical connection of the light-emitting device to an external device,
in the top view,
the first area is located between the first fixing portion and the second fixing portion,
the second fixing portion is disposed between the first electrode portion and the second electrode portion, and
the substrate has the longitudinal direction extending in the first direction and a widthwise direction extending in the second direction.

2. The light-emitting module according to claim 1, further comprising the connecting member, wherein the connecting member is a connector.

3. The light-emitting module according to claim 2, wherein
the connector has a widthwise direction extending in the first direction and a lengthwise direction extending in the second direction in the top view.

4. The light-emitting module according to claim 3, wherein
the light-emitting device, the first fixing portion, the second fixing portion, and the second electrode portion are arranged so that a virtual straight line parallel with the first direction passes through the light-emitting device, the first fixing portion, the second fixing portion, and the second electrode portion in the top view.

5. The light-emitting module according to claim 4, wherein
the virtual straight line passes through a midpoint of a width of the wiring board in the widthwise direction in the top view.

6. The light-emitting module according to claim 1, wherein
the light-emitting device, the first fixing portion, the second fixing portion, and the second electrode portion are arranged so that a virtual straight line parallel with the first direction passes through the light-emitting device, the first fixing portion, the second fixing portion, and the second electrode portion in the top view.

7. The light-emitting module according to claim 6, wherein
the virtual straight line passes through a midpoint of a width of the wiring board in the widthwise direction in the top view.

8. The light-emitting module according to claim 1, wherein
the wiring board includes an insulating member located on the mounting surface,
the first electrode portion and the second electrode portion are exposed from the insulating member,
the first electrode portion includes a plurality of first electrode areas that are not electrically connected with one another,
the second electrode portion includes a plurality of second electrode areas that are not electrically connected with one another, and
a length of the first electrode portion from one end to an opposite end in the second direction is larger than a length of the second electrode portion from one end to an opposite end in the second direction.

9. The light-emitting module according to claim 1, wherein each of the first fixing portion and the second fixing potion is a through-hole through which a screw is configured to be inserted to fasten the wiring board.

10. The light-emitting module according to claim 1, further comprising
a temperature measuring element configured to measure a temperature, wherein
the temperature measuring element is disposed between the second fixing portion and the second electrode portion on the mounting surface of the wiring board, in the top view.
